(19) United States
(12) Patent Application Publication
(10) Pub. No.: US 2026/0026108 A1
(43) Pub. Date: Jan. 22, 2026

(54) SEMICONDUCTOR STRUCTURE AND MANUFACTURING METHOD THEREOF

(71) Applicants: TAIWAN SEMICONDUCTOR MANUFACTURING COMPANY, LTD., Hsinchu (TW); TSMC CHINA COMPANY LIMITED, Shanghai (CN)

(72) Inventors: Huan-Neng CHEN, Taichung City (TW); Shao-Yu LI, Hsinchu City (TW); CunCun CHEN, Shanghai City (CN)

(73) Assignees: TAIWAN SEMICONDUCTOR MANUFACTURING COMPANY, LTD., Hsinchu (TW); TSMC CHINA COMPANY LIMITED, Shanghai (CN)

(21) Appl. No.: 18/791,060

(22) Filed: Jul. 31, 2024

(30) Foreign Application Priority Data
Jul. 19, 2024 (CN) 202421727962.2

(51) Int. Cl. H01L 27/02

(52) U.S. Cl. CPC H10D 89/814

(57) ABSTRACT

A method includes forming first and second transistors over a substrate, the first and second transistors being parts of a buffer circuit in an input/output (I/O) circuit; forming a third transistor over the substrate and interposing between the first and second transistors from a cross-sectional view, the third transistor being a part of an electrostatic discharge (ESD) circuit in the I/O circuit; forming a first metal line horizontally extending from above the first transistor across the third transistor to above the second transistor, wherein the first metal line is electrically coupled to the first, second, and third transistors.

### PRIORITY CLAIM AND CROSS-REFERENCE

This application claims priority to CN application No. 202421727962.2, filed Jul. 19, 2024, which is herein incorporated by reference.

### BACKGROUND

Semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed.

In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling-down also produces a relatively high power dissipation value, which may be addressed by using low power dissipation devices such as complementary metal-oxide-semiconductor (CMOS) devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic block diagram of an IC device in accordance with some embodiments of the present disclosure.

FIG. 1B illustrates a schematic plan circuit diagram of a buffer circuit with an electrostatic discharge (ESD) protection circuit in accordance with some embodiments of the present disclosure.

FIG. 1C illustrates a schematic plan circuit diagram of a buffer circuit with an ESD protection circuit in accordance with some embodiments of the present disclosure.

FIG. 2A illustrates a top view layout pattern of an IC structure including a buffer circuit with an ESD protection circuit in accordance with some embodiments of the present disclosure.

FIG. 2B illustrates a top view layout pattern of an IC structure including a buffer circuit with an ESD protection circuit in accordance with some embodiments of the present disclosure.

FIG. 3A illustrates a schematic cross-sectional view of an IC structure including a buffer circuit with an ESD protection circuit in accordance with some embodiments of the present disclosure.

FIG. 3B-3K illustrate cross-sectional views of the IC structure obtained from reference cross-sections B1-B1′, B2-B2′, B3-B3′, B4-B4′, B5-B5′, and B6-B6′ in FIG. 2A in accordance with some embodiments of the present disclosure.

FIG. 4 illustrates a top view layout pattern of an IC structure including a buffer circuit with an ESD protection circuit over a substrate in accordance with some embodiments of the present disclosure.

FIGS. 5A-5F illustrate schematic cross-sectional views of an IC structure at intermediate stages of fabrication process in accordance with some embodiments of the present disclosure.

FIG. 6 is a schematic diagram of an electronic design automation (EDA) system in accordance with some embodiments of the present disclosure.

FIG. 7 is a block diagram of an IC manufacturing system and an IC manufacturing flow associated therewith, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In 3D integrated circuit (3DIC) packages (e.g., Chip-on-Wafer-on-Substrate (CoWoS) packages, Integrated Fan-Out (InFO) wafer level packages, Systom on Integrated Chips (SoIC) packages, or the like), electromigration (EM) management in die-to-die input/output (I/O) circuits for routing metal widths and vias is tailored to comply with electrostatic discharge (ESD) standards. One issue is the sequence of connecting die-to-die pads, first to an ESD circuit and then to the buffer circuit. This creates a horizontal current path, leading to current crowding and degraded EM conditions.

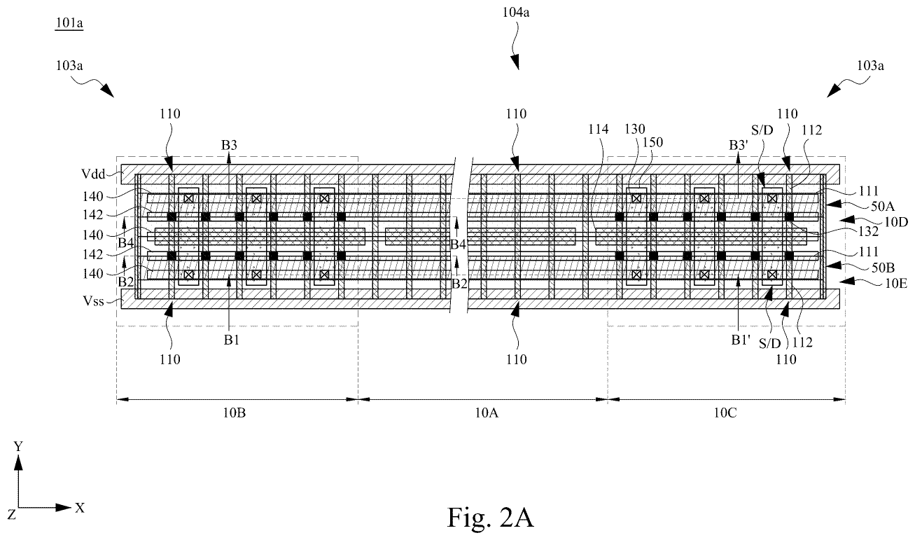

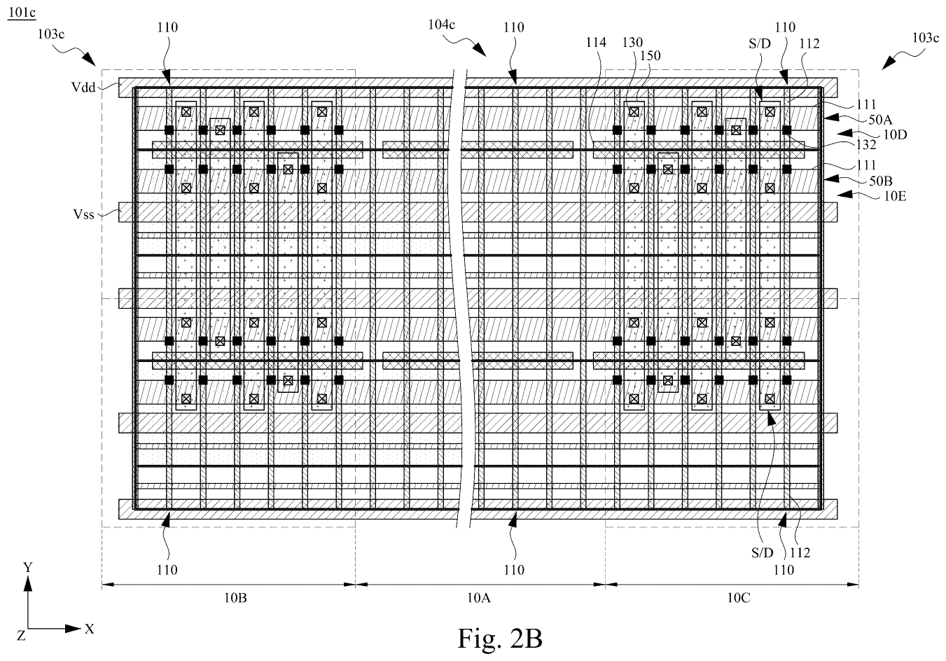

Therefore, the present disclosure in various embodiments provides a method to enhance the performance of die-to-die I/O circuits in 3DIC. The I/O circuit can integrate a buffer circuit with an ESD protection structure. A driving strength of the buffer circuit (e.g., 16 PMOS and 16 NMOS transistors) can be divided into two sub-buffer regions (e.g., buffer circuit regions 10B and 10C shown in FIG. 2A), each wielding half of the total driving strength (e.g., 8 PMOS and 8 NMOS). Specifically, for output stage, the transistors in the sub-buffer regions connect their source/drain regions to those in the ESD protection region via a horizontal metal line. The two sub-buffer regions can be positioned on opposite sides of the ESD protection region (e.g., ESD protection circuit region 10A shown in FIG. 2A). This arrangement can split and shorten the horizontal current path, reducing the length of the current path to between 50% and 75% of its original length, leading to a decrease in output capacitance loading and boosts electromigration resilience.

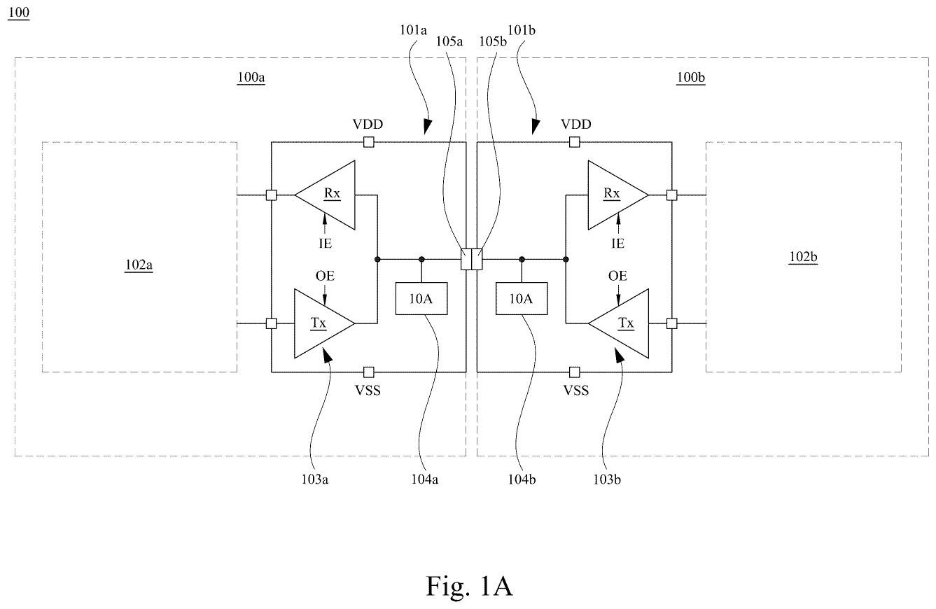

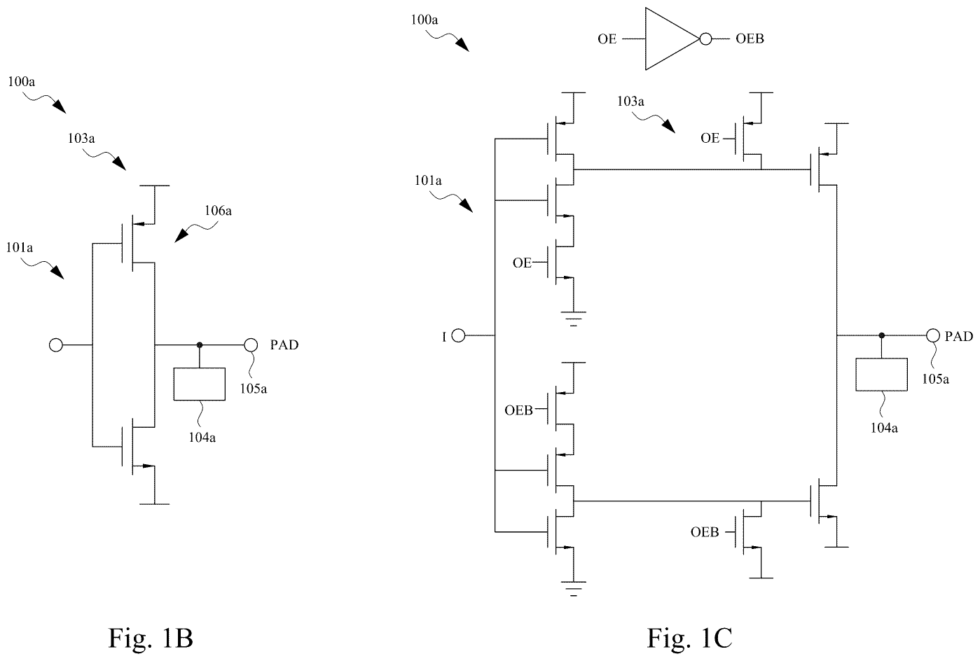

Reference is made to FIGS. 1A-1C. FIG. 1A illustrates a schematic block diagram of an IC device 100 in accordance with some embodiments of the present disclosure. FIG. 1B illustrates a schematic plan circuit diagram of a buffer circuit 103a combined with an electrostatic discharge (ESD) protection circuit 104a within the IC device 100 in accordance with some embodiments of the present disclosure. FIG. 1C illustrates a schematic plan circuit diagram of a buffer circuit 103b combined with an ESD protection circuit 104b within the IC device 100 in accordance with some embodiments of the present disclosure.

As shown in FIG. 1A, the IC device 100 comprises a first die 100a and a second die 100b electrically and/or physically coupled to each other. In some embodiments, the first die 100a and the second die 100b are stacked over each other, and are physically bonded and electrically coupled to each other in a 3D IC through pads 105a and 105b thereof. In some embodiments, the first die 100a and the second die 100b are arranged side-by-side on and physically bonded to a further substrate or die (not shown), and are electrically coupled to each other through the further substrate or die. In some embodiments, the IC device 100 comprises more than two dies electrically and/or physically coupled to each other. In some embodiments, the IC device 100 has one die, e.g., the first die 100a, whereas the other die, e.g., the second die 100b, is omitted. In the example configuration in FIG. 1A, the second die 100b is configured similarly to the first die 100a. The first die 100a is described in detail herein, and a detailed description of the second die 100b is omitted. The first die 100a can include one or more functional circuits and one or more input/output (I/O) circuits electrically coupled to the one or more functional circuits. In FIG. 1A, a representative I/O circuit 101a and a representative functional circuit 102a of the first die 100a are illustrated. In some embodiment, the I/O circuit 101b and the functional circuit 102b of the second die 100b can correspond to the I/O circuit 101a and the functional circuit 102a of the first die 100a.

In some embodiment, the functional circuit 102a can be configured to perform an intended function, e.g., data processing or data storage, of the IC device 100. Examples of one or more circuits, logics, or cells included in the functional circuit 102a include, but are not limited to, AND, OR, NAND, NOR, XOR, INV, OR-AND-Invert (OAI), MUX, Flip-flop, BUFF, Latch, delay, clock, memory, or the like. The circuits, logics, or cells included in the functional circuit 102a include functional transistors or core transistors which are to be protected from the antenna effect during the manufacture of the IC device 100. Examples of transistors in the functional circuit 102a, as well as in the other circuits described herein, include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like.

In some embodiment, the I/O circuit 101a can be electrically coupled to the functional circuit 102a, and can be configured as an interface between the functional circuit 102a on the first die 100a and external circuitry outside the first die 100a. In the example configuration in FIG. 1A, the I/O circuit 101a can include the buffer circuit 103a and the ESD protection circuit 104a, in which the buffer circuit 103a may include a receiving circuit Rx (also referred to as “input circuit”) and a transferring circuit Tx (also referred to as “output circuit”), and all of which are electrically coupled to a pad 105a which can be an I/O pin. In some embodiment, the buffer circuit 103b, the ESD protection circuit 104b, and the pad 105b of the second die 100b can correspond to the buffer circuit 103a, the ESD protection circuit 104a, and the pad 105a of the first die 100a. In some embodiment, the pad 105a can be interchangeable referred to as a metal pad, a pad pin, or a die-to-die pad.

The buffer circuit 103a can be used to strengthen and stabilize the signals being transmitted in and out of the die 100a. In some embodiments, the buffer circuit 103a can condition the signal, such as inverting it (e.g., inverter buffer shown in FIG. 1B) or providing multiple states (e.g., tri-state buffer shown in FIG. 1C). In some embodiments, the buffer circuit 103a can provide isolation between circuits, protecting a circuit from the potentially harmful effects of the connected circuit. In some embodiments, the buffer circuit 103a can be changeable referred to as an ESD victim.

In some embodiment, the receiving circuit Rx in the buffer circuit 103a can be configured to send a signal on the pad 105a to the functional circuit 102a. The receiving circuit Rx can be configured to receive an input enable signal IE. The receiving circuit Rx can be enabled to send the signal on the pad 105a to the functional circuit 102a in response to a logic state of the input enable signal IE, and can be disabled from sending the signal on the pad 105a to the functional circuit 102a in response to a different logic state of the input enable signal IE. The transferring circuit Tx in the buffer circuit 103a can be configured to send a signal output by the functional circuit 102a to the pad 105a. The transferring circuit Tx can be configured to receive an output enable signal OE. The transferring circuit Tx can be enabled to send the signal output by the functional circuit 102a to the pad 105a in response to a logic state of the output enable signal OE, and can be disabled from sending the signal output by the functional circuit 102a to the pad 105a in response to a different logic state of the output enable signal OE. Examples of the signal(s) input from or output to the pad 105a include, but are not limited to, data, power, clock, control, or the like. Examples of one or more circuits in at least one of the receiving circuit Rx or transferring circuit Tx include, but are not limited to, a buffer, a latch, a level shifter, or the like.

In some embodiment, the ESD protection circuit 104a can be configured to protect the other circuits, including the functional circuit 102a, that are electrically coupled to the pad 105a from ESD events occurring on the pad 105a during operation or handling of the first die 100a or IC device 100. By way of example and not limitation, the ESD protection circuit 104a can employ components like diodes to clamp the voltage to a safe level when an ESD event occurs, preventing the voltage spike from reaching and damaging the sensitive parts in the die 100a. In some embodiment, the ESD protection circuit 104a can serves to divert the excess current away from sensitive circuit components. Examples of the ESD protection circuit 104a include, but are not limited to, a diode, a grounded-gate NMOS (ggNMOS), a silicon-controlled rectifier (SCR), or the like. In some embodiments, transistors in the ESD protection circuit 104a can be larger than and/or have a different configuration from the functional transistors or core transistors of the functional circuit 102a to be able to sustain and handle high voltages and/or current of ESD events.

In some embodiment, the first die 100a is electrically coupled to the second die 100b at one or more die-to-die interconnects. In FIG. 1A, a representative die-to-die interconnect is illustrated, and is electrically coupled to the pad 105a of the first die 100a and to a corresponding pad 105a of the second die 100b. As a result, the pad 105a of the first die 100a is electrically coupled to the corresponding pad 105b of the second die 100b through the die-to-die interconnect. In some embodiments, the die-to-die interconnect can be a TSV in one or more dies of the IC device 100.

Reference is made to FIGS. 1B and 1C. FIGS. 1B and 1C illustrate different configurations of the I/O circuit 101a within the die 100a, focusing on variations in the buffer circuit 103a. As shown in FIG. 1B, the buffer circuit 103a can include an inverter 106a. The inverter 106a can be a fundamental digital logic circuit that flips the input signal's state; if the input is high (e.g., 1), the output is low (e.g., 0), and vice versa. The inverter 106a in the buffer circuit 103a can include of at least one pair of transistors (e.g., an NMOS transistor and a PMOS transistor). The ESD protection circuit 104a can be used to safeguard the inverter 106a and other components from electrostatic discharge damage. The pad 105a can serve as the interface for the buffer circuit's output. In this case, the output of the inverter 106a can be routed to pad 105a, providing a signal inversion for external communication or further internal processing within the die 100a.

As shown in FIG. 1C, the buffer circuit 103a can incorporate a tri-state buffer. The tri-state buffer can be in one of three states: high, low, or high-impedance, allowing for further control and interaction with bus systems or shared signal lines. The transistor arrangement in the tri-state buffer may include additional transistors controlled by enable signals to achieve the high-impedance state. The signals (e.g., output enable OE and output enable bar OEB) can control the state of the tri-state buffer. The output enable OE might activate the buffer (allowing normal operation), while the output enable bar OEB could put the buffer into a high-impedance state, disconnecting it from the output pad 105a. The ESD protection circuit 104a can be used to safeguard the tri-state buffer and other components from electrostatic discharge damage. The pad 105a can serve as the interface for the tri-state buffer's output. In this case, depending on the state controlled by the output enable OE and the output enable bar OEB, the pad 105a may receive either a high or low signal, or be electrically disconnected from the buffer circuit 103a.

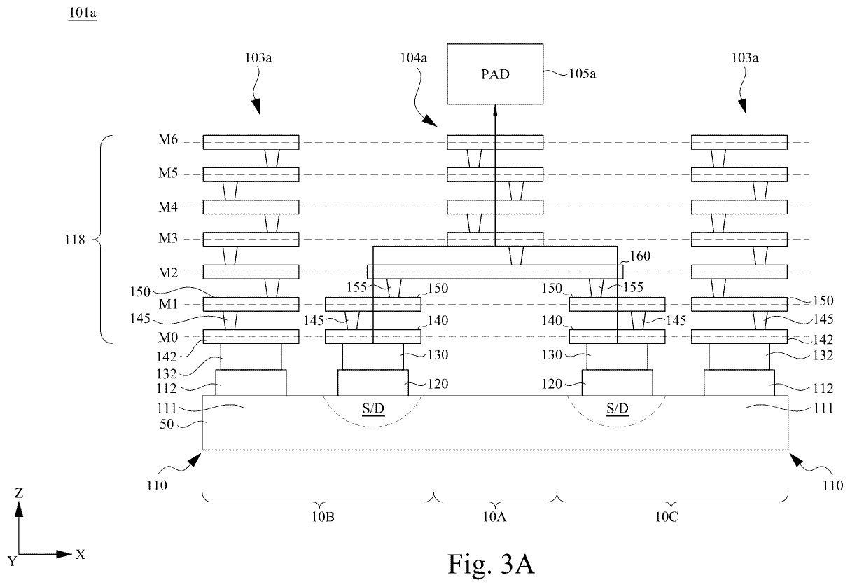

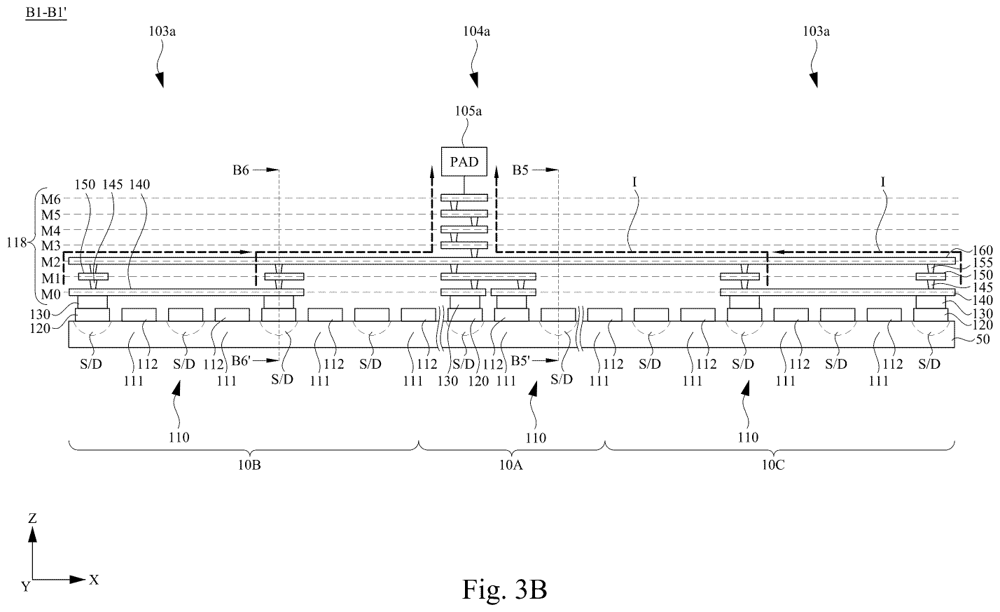

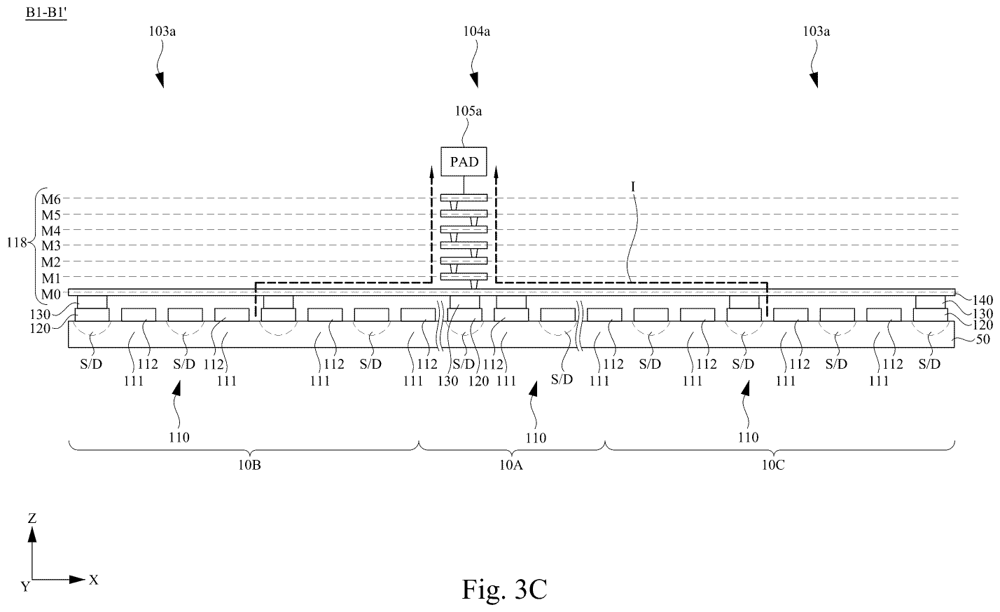

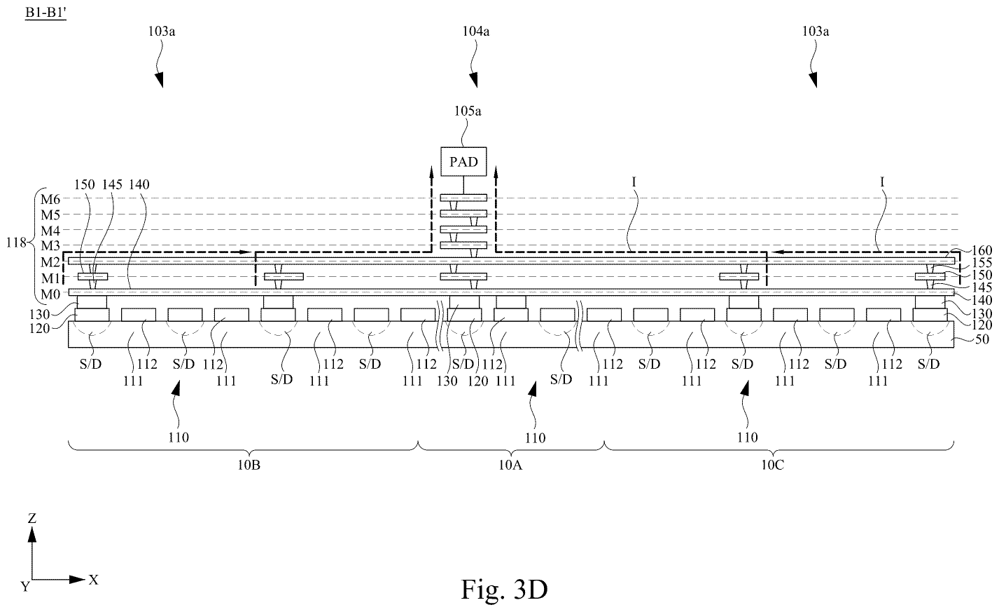

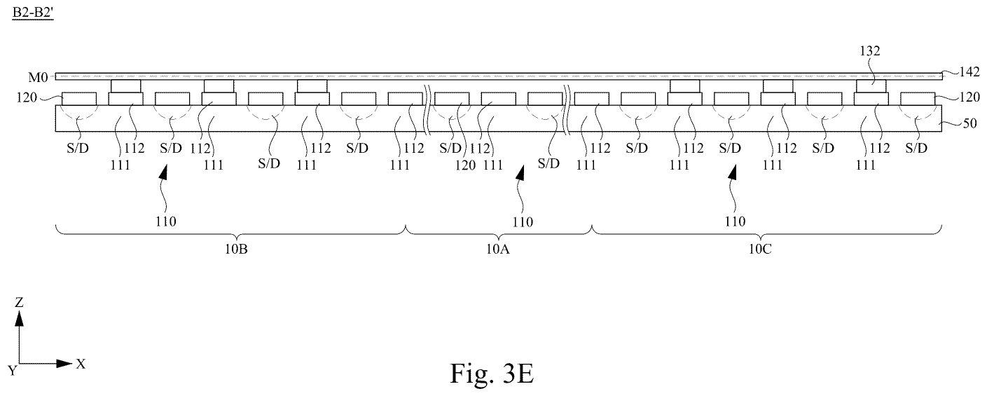

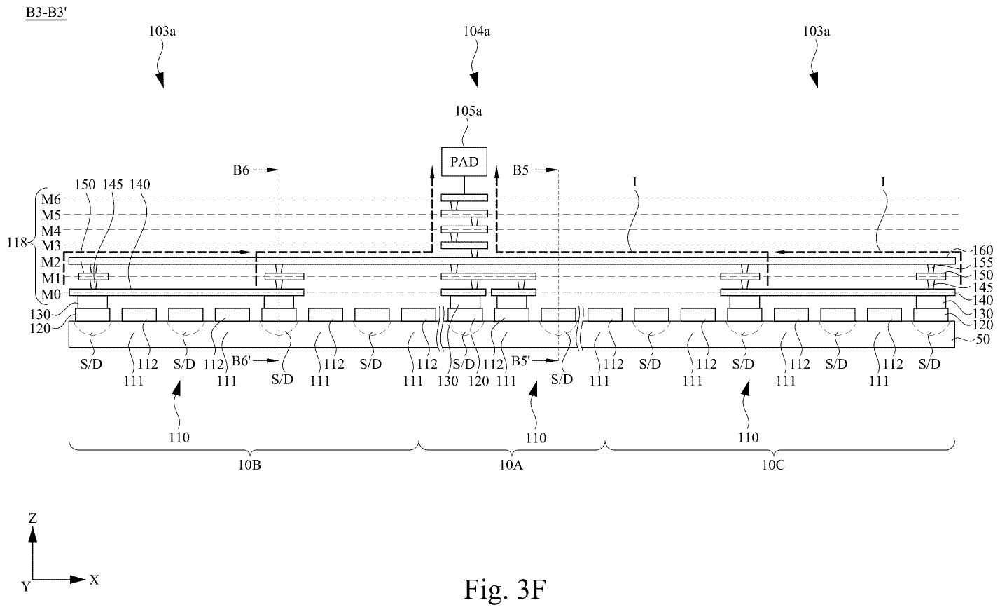

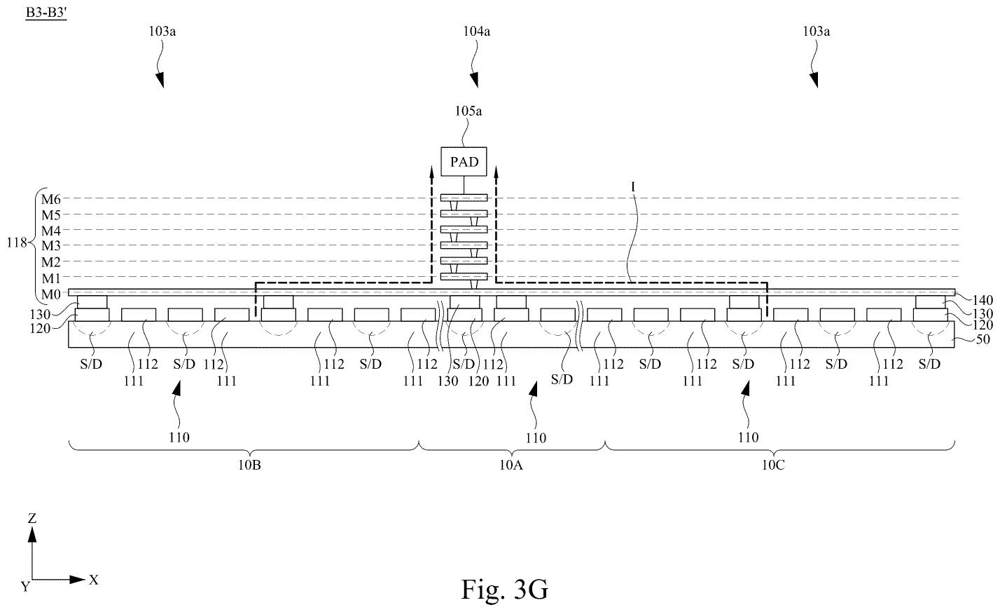

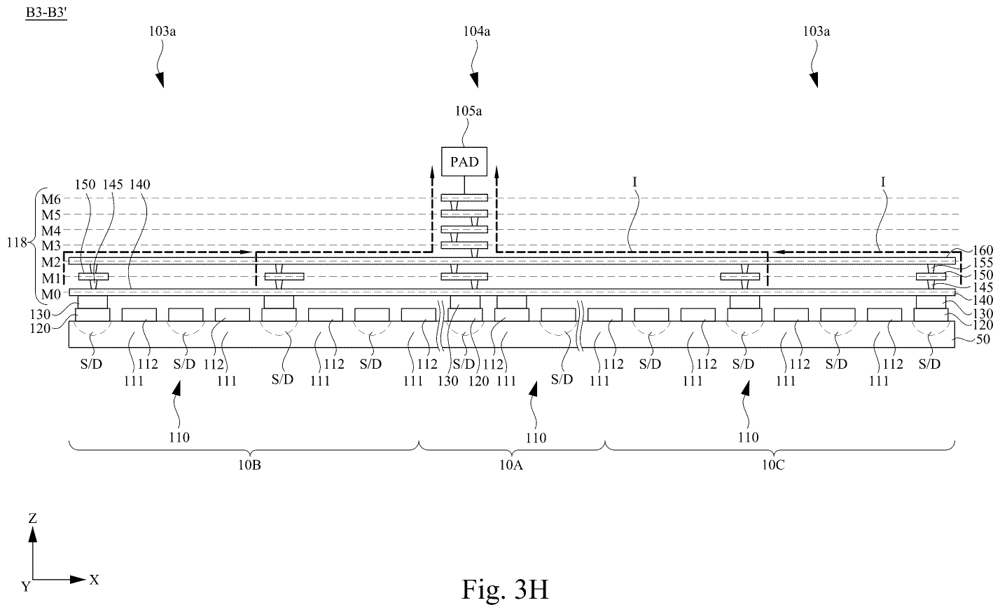

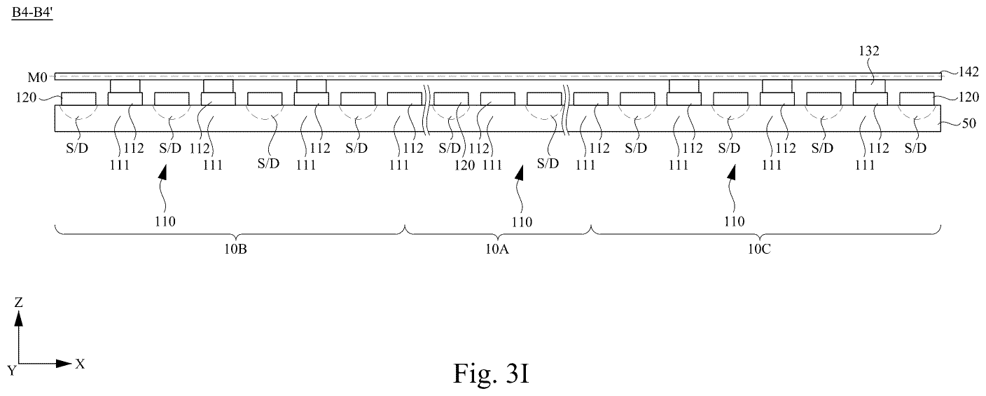

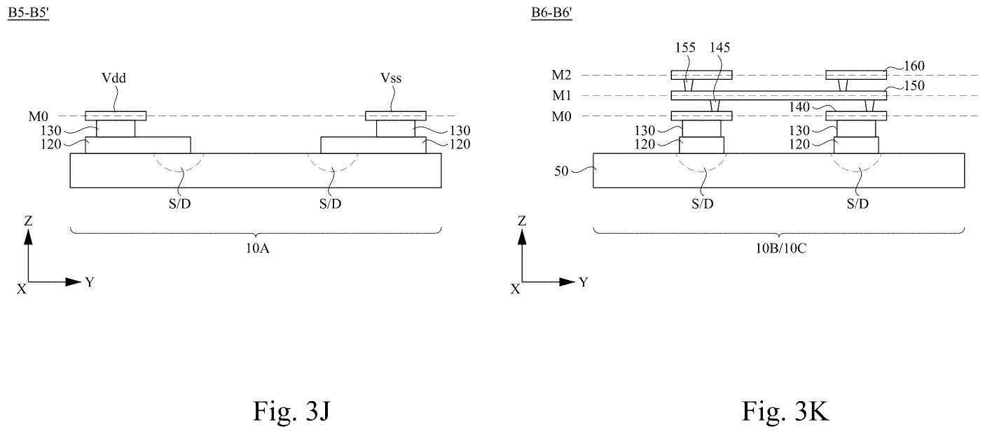

Reference is made to FIGS. 2A and 3A-3K. FIG. 2A illustrates a top view layout pattern of the I/O circuit 101a including the buffer circuit 103a with the ESD protection circuit 104a in accordance with some embodiments of the present disclosure. FIG. 3A illustrates a schematic cross-sectional view of the I/O circuit 101a including a buffer circuit 103a with an ESD protection circuit 104a in accordance with some embodiments of the present disclosure. FIG. 3B illustrate cross-sectional views of the I/O circuit 101a obtained from a reference cross-section B1-B1′ in FIG. 2A in accordance with some embodiments of the present disclosure. FIGS. 3C and 3D illustrate cross-sectional views of IC structures corresponding to FIG. 3B in accordance with some embodiments of the present disclosure. FIG. 3E illustrates a cross-sectional view of the I/O circuit 101a obtained from a reference cross-section B2-B2′ in FIG. 2A in accordance with some embodiments of the present disclosure. FIG. 3F illustrates a cross-sectional view of the I/O circuit 101a obtained from a reference cross-section B3-B3′ in FIG. 2A in accordance with some embodiments of the present disclosure. FIGS. 3G and 3H illustrate cross-sectional views of IC structures corresponding to FIG. 3F in accordance with some embodiments of the present disclosure. FIG. 31 illustrates a cross-sectional view of the I/O circuit 101a obtained from a reference cross-section B4-B4′ in FIG. 2A in accordance with some embodiments of the present disclosure. FIG. 3J illustrates a cross-sectional view of the I/O circuit 101a obtained from a reference cross-section B5-B5′in FIGS. 3B and 3F in accordance with some embodiments of the present disclosure. FIG. 3K illustrates a cross-sectional view of the I/O circuit 101a obtained from a reference cross-section B6-B6′ in FIGS. 3B and 3F in accordance with some embodiments of the present disclosure.

As shown in FIGS. 2A and 3A, the I/O circuit 101a can have an ESD protection circuit region 10A, a first buffer circuit region 10B, and a second buffer circuit region 10C arranged over a substrate 50 (see FIG. 3A). The ESD protection circuit region 10A can be situated (or localized) between the first and second buffer circuit regions 10B and 10C. It should be noted that the configuration of the ESD protection circuit region 10A and the first and second buffer circuit regions 10B and 10C in the I/O circuit 101a are used as an illustration, and not to limit the disclosure. In other words, the transistor in the ESD protection circuit region 10A can interpose between the transistor 110 in the first buffer circuit region 10B and the transistor 110 in the second buffer circuit region 10C (see FIG. 3B). By way of example but not limiting the present disclosure, the first and second buffer circuit regions 10B and 10C each may have at least one inverter.

The pad 105a (see FIG. 3A) first connects to the ESD circuit 104a on the ESD protection circuit region 10A before routing to the buffer circuit 103a on the first and second buffer circuit region 10B/10C. This means that for buffer circuit 103a, the initial connection can be with the ESD protection circuit 103a. This connection order can lead to a horizontal current path (e.g. metal line 160 shown in FIG. 3A) between the pad 105a and the transmitter in the buffer circuit 103a on the first and second buffer circuit region 10B/10C. The pad 105a electrically connects to the ESD protection circuit 103a (e.g., source/drain region S/D of transistor 110 within the ESD protection region 10A shown in FIG. 3B) through various interconnect, such as hybrid bump, microbump (ubump), or through-silicon via (TSV). In FIG. 3A, for the output stage, the source/drain region S/D of the transistor 110 in the ESD protection region 10A is electrically connected to the source/drain region S/D of another transistor 110 (which acts as a transmitter) in the buffer region 10B/10C through the horizontal metal line 160. On the contrary, for the input stage, the source/drain region S/D of the transistor 110 in the ESD protection region 10A is electrically connected to a gate structure of a different transistor 110 (serving as a receiver) in the buffer region 10B/10C.

In some embodiments, the time rise and fall of signals in the circuit should be less than one-sixth of the operating period. This requirement may indicate that the operating speed of the die-to-die I/O circuit can be limited by electromigration (EM) issues. In some embodiments, the speed of the die-to-die I/O circuit may be limited by electromigration in the horizontal trace (e.g. metal line 160 shown in FIG. 3A), in which the horizontal trace may have potential current crowding.

The buffer circuit 103a can be built in a semiconductor structure that is divided into two sub-buffer regions (e.g., first and second buffer circuit regions 10B and 10C). By placing the first and second buffer circuit regions 10B and 10C on opposite sides of the ESD protection region 10A, the horizontal current path in the metal line (e.g. metal line 160 shown in FIG. 3A) is split and shortened. This reduction in the length of the current path (to about 50% to 75% of its original length) can alleviate issues related to current crowding and electromigration. In some embodiments, shorter horizontal metal lines can lead to lower output capacitance loading. This can result in an electromigration boost, allowing for higher speed and driving capability for heavy loads, which in turn improves electromigration/IR-drop (EMIR) issues without degrading the rise/fall time of signals. Therefore, the I/O circuit 101a can reduce the stress caused by electromigration by greater than about 50%, such as about 50, 55, 60, 65, 70, 75, 80, 85, 90%, and 95%. By reducing stress, the I/O circuit 101a can extend the lifespan of the circuit. Additionally, the I/O circuit 101a can achieve an electromigration relaxation greater than about 1.7 times, indicating that the circuits are substantially more resistant to the damaging effects of electron. Moreover, the I/O circuit 101a can offer a speed boost greater than about 1.15 times.

Furthermore, the total driving strength of the buffer circuit 103a, represented by a certain number of PMOS and NMOS transistors (e.g., 12 PMOS transistors and 12 NMOS transistors), is divided into two sub-buffer regions. Each sub-buffer region then possesses a portion of the total driving strength (e.g., 6 PMOS transistors and 6 NMOS transistors as shown in FIG. 2A) and has its own set of transistors, and the first and second buffer circuit regions 10B and 10C are located on opposite sides of the ESD protection region 10A.

Specifically, as shown in FIGS. 2A and 3A, the I/O circuit 101a may include transistors 110 within a first conductivity type device region 10D (see FIG. 2A) and a second conductivity type device region 10E (see FIG. 2A) over the substrate 50 (see FIG. 3A). In some embodiments, the transistors 110 in the first conductivity type device region 10D may be PMOSFET transistors with silicon channel regions, and the transistors in the second conductivity type device region 10E may be NMOSFET transistors with silicon channel regions. In some embodiments, the transistors may be GAA FETs, and thus the silicon channel regions of the NMOS and PMOS transistors can be formed by semiconductor sheets (not shown). In some embodiments, a second conductivity type well 50A (see FIG. 2A) and a first conductivity type well 50B (see FIG. 2A) can be formed in the substrate 50. By way of example but not limiting the present disclosure, the second conductivity type well 50A may be a n-well, and the first conductivity type well 50B may be p-well.

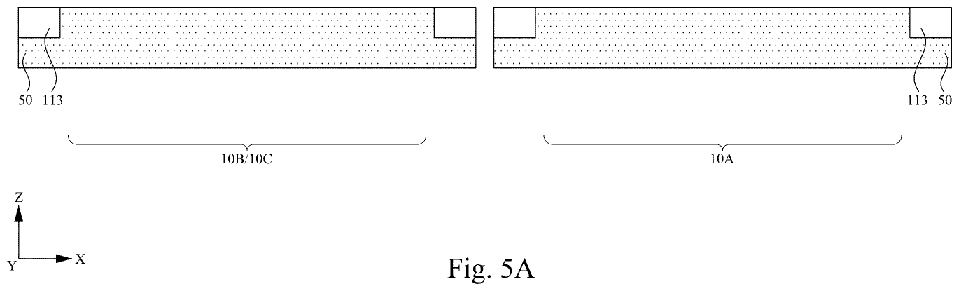

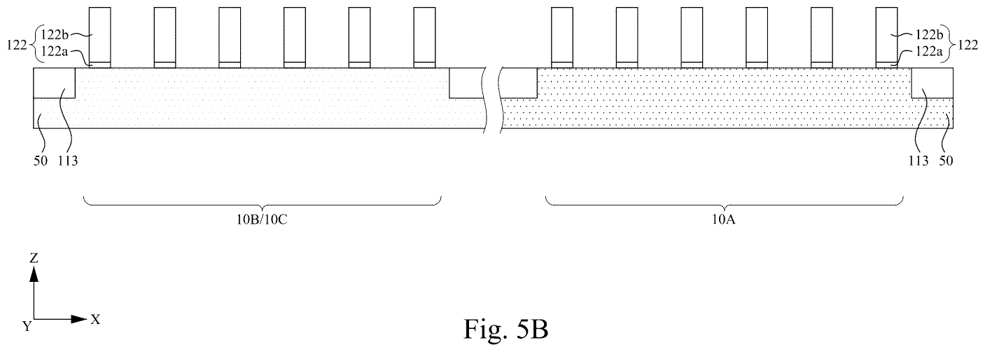

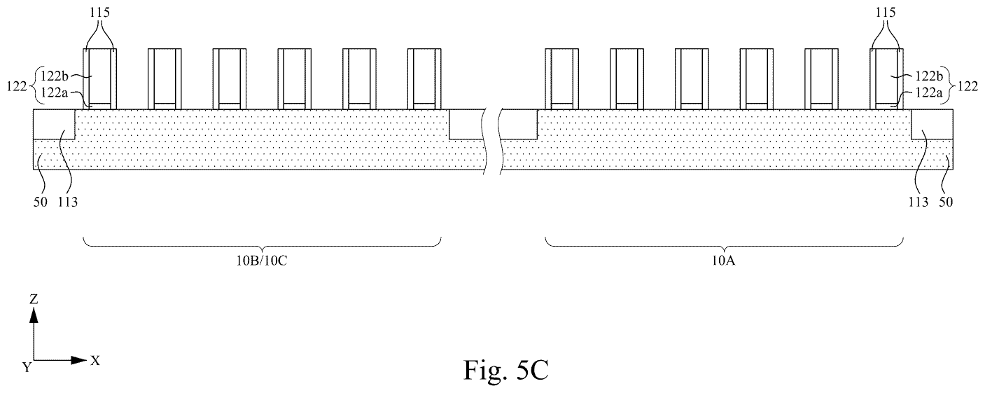

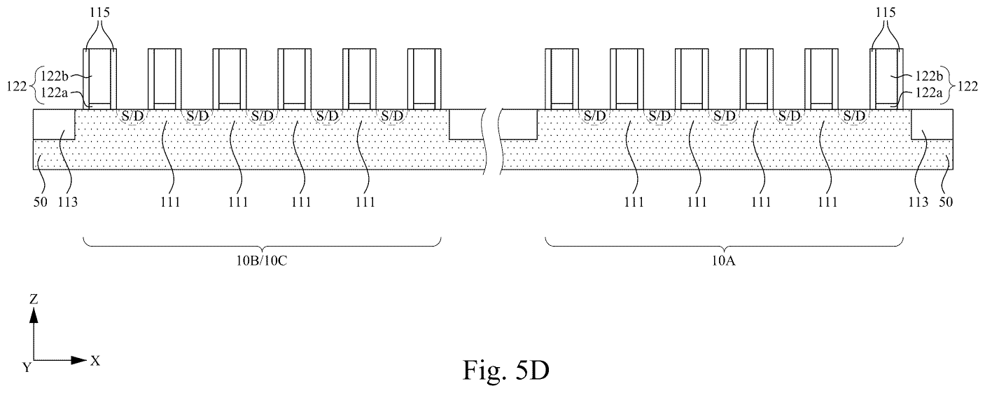

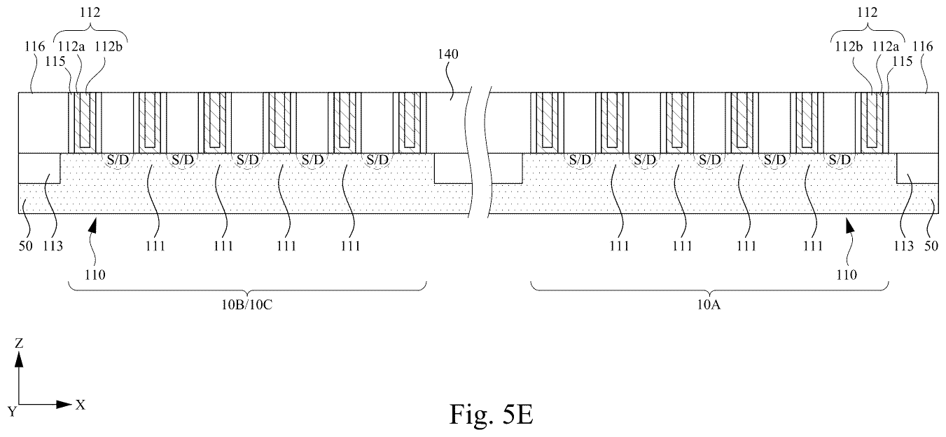

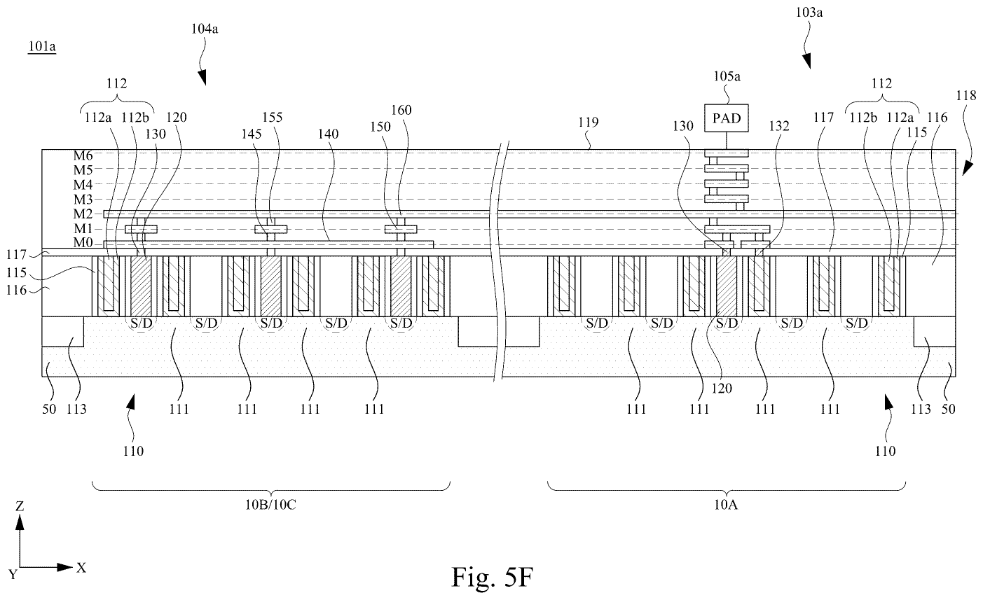

The transistors 110 can include channel regions 111 formed over the first and second conductivity type wells 50B and 50A (see FIG. 2A). The transistors 110 can further include gate structures 112 within the ESD protection circuit region 10A and the buffer circuit regions 10B and 10C and extending in the Y-direction. The gate structure 112 can include a gate dielectric layer 112a (see FIGS. 5E and 5F) around the channel region 111, and a gate electrode layer 112b (see FIGS. 5E and 5F) formed over the gate dielectric layer 112a. In some embodiment, the gate structure 112 can be interchangeable referred to as a functional gate, a gate strip, a gate pattern, or a gate layer. The transistors 110 can further include source/drain regions S/D over the channel region 111 and at opposite sides of the gate structure 112. In some embodiments, a dopant in the source/drain region S/D of the first conductivity type device region 10D (see FIG. 2A) has an opposite conductivity type to a dopant in the source/drain region S/D of the second conductivity type device region 10E (see FIG. 2A). For example, the source/drain region S/D of the first conductivity type device region 10C may have an p-type dopant, and the source/drain region S/D of the second conductivity type device region 10E may have an n-type dopant.

In FIG. 2A, the I/O circuit 101a can include cut polysilicon (CPO) structure 114, which can be used to separate adjacent gate structures 112. The cut polysilicon structure 114 can be used for isolating individual transistors 110 or transistor groups within the I/O circuit 101a. In some embodiments, the cut polysilicon structure 114 can be made of a dielectric material and can be changeable referred to as an isolation structure, an isolation strip, or an an isolation line pattern.

In some embodiments, a source/drain region S/D can be electrically coupled to an overlying metal line in an interconnect structure 118 (see FIG. 3A) through a source/drain contact 120 (see FIG. 3A) and a source/drain via 130 (see FIG. 3A). The gate structure 112 can be electrically connected to another overlying level metal line in the interconnect structure through a gate via 132. The interconnect structure 118 can be formed over the transistors 110 and may include, for example, seven metallization layers, labeled as M0, M1, M2, M3, M4, M5, and M6, with a plurality of layers of metallization via connected therebetween. Other embodiments may contain more or fewer metallization layers and corresponding more or fewer number of vias. The metal line illustrated here just for an example, and the metal line may be otherwise oriented (rotated 90 degrees or at other orientations).

In some embodiments, metal lines disposed at the M0 level (see FIG. 3A) over the substrate 50 may include a power supply voltage line Vss (see FIG. 2A), a power supply voltage line Vdd (see FIG. 2A), a metal line 140 (see FIGS. 3A, 3B and 3F), and a metal line 142 (see FIGS. 3A, 3E and 3I). The metal lines disposed at the M0 level may have lengthwise directions in parallel to the X-direction. In some embodiments, the buffer circuit 103a can be powered through the power supply voltage line Vdd, and the power supply voltage lines Vss can be provided with an electrical ground. The power supply voltage lines Vdd and Vss can be electrically connected to source terminals of the first and second buffer circuit regions 10B and 10C (see FIG. 2A) through the source/drain contacts 120 (see FIG. 3A) and the source/drain vias 130. The metal lines 140 and 142 can be laterally between the power supply voltage lines Vdd and Vss. The metal line 140 can be electrically connected to drain terminals of the source/drain regions S/D in the first and second buffer circuit regions 10B and 10C (see FIGS. 2A, 3A, and 3F) through the source/drain contacts 120 and the source/drain vias 130. The metal line 142 can be electrically connected to the gate structure 112 in the first and second buffer circuit regions 10B and 10C through the gate via 132 (see FIGS. 2A, 3E, and 3I). In some embodiments, the metal line 142 can extend beyond opposite boundaries of the ESD protection region 10A and to reach the divided first and second buffer circuit regions 10B and 10C. In some embodiments, the metal line 142 can extend across the ESD protection region 10A and the first and second buffer circuit regions 10B and 10C. In some embodiments, a length of the metal line 142 can be longer than a length of the metal line 140.

In some embodiments, metal lines disposed at the M1 level over the M0 level may include metal lines 150 (see FIGS. 3A, 3B, and 3F). The metal lines disposed at the M1 level may have lengthwise directions in parallel to the Y-direction. The metal lines 150 can be electrically connected to the metal lines 140/142 (see FIGS. 3A, 3B and 3F) in the first and second conductivity type device regions 10D and 10E (see FIG. 2A) through underlying vias 145.

In some embodiments, metal lines disposed at the M2 level over the M1 level may include metal lines 160 (see FIGS. 3A, 3B and 3F). The metal lines disposed at the M2 level may have lengthwise directions in parallel to the X-direction. The metal lines 160 can be electrically connected to the metal lines 150 (see FIGS. 3A, 3B, and 3F) through underlying vias 155. In other words, as shown in FIGS. 3B and 3F, the source/drain region S/D of the transistor 110 in the buffer circuit 103a can be electrically connected to the source/drain region S/D of another transistor 110 in the ESD protection circuit 103a through the horizontal metal line 160 (i.e., horizontal current path). In some embodiments, the speed of the die-to-die I/O circuit may be limited by electromigration in the metal line 160. The metal line 160 can extend beyond opposite boundaries of the ESD protection region 10A and to reach the divided first and second buffer circuit regions 10B and 10C, which in turn reduces in the length of the current path, such that current crowding and electromigrationcan issues can be alleviated.

In some embodiments, the metal line 160 can extend across the ESD protection region 10A and the first and second buffer circuit regions 10B and 10C, such that the metal line 160 can extend across the gate structures 112 in the ESD protection region 10A and the first and second buffer circuit regions 10B and 10C. The metal line 160 can horizontally extend from above the transistor 110 in the first buffer circuit region 10B across the transistor 110 in the ESD protection region 10A to above the transistor 110 in the second buffer circuit region 10C. In some embodiments, the metal line 160 has a length greater than underlying metal line 140 connected to the source/drain vias 130. In some embodiments, the metal line can be interchangeable referred to as a trace and a path. In some embodiments, materials of the lines Vss, Vdd, 140, 142, 150, and 160, the contact 120, and/or the vias 130 and 132 may be made of Cu, Co, Ru, Pt, Al, W, Ti, TaN, TiN, or any combinations thereof.

FIGS. 3B-3D and 3F-3H illustrate various methods of connecting the buffer circuit 103a to the ESD protection circuit 104a. These methods utilize different metal line levels (e.g., M0 level, M2 level) within the IC structure to establish this connection. This flexibility can allow for optimizing the signal transmission paths (e.g., marked with dotted lines in FIGS. 3B-3D and 3F-3H).

In FIGS. 3C and 3G, the connection between the buffer circuit 103a and the ESD protection circuit 104a can be established using the metal line 140 at the M0 level, which provides a path for signal transmission from the buffer circuit 103a to the ESD protection circuit 104a, simplifying the overall layout. The dotted line in FIGS. 3C and 3G illustrate the flow of the signal I through the metal line 140. In FIGS. 3D and 3H, the connection between the buffer circuit 103a and the ESD protection circuit 104a can be established using both the metal line 140 at the M0 level and the metal line 160 at the M2 level, which provides a flexibility in routing and reduces electromigration or enhancing signal integrity. The dotted line in FIGS. 3D and 3H illustrate the flow of the signal I through the metal line 140. In FIGS. 3B and 3F, the connection between the buffer circuit 103a and the ESD protection circuit 104a can be established using the metal line 160 at the M2 level. In some embodiments, this higher-level metal line (e.g. M4 level or M6 level) can be used for longer connections or to navigate around other components in the IC structure. The dotted line in FIGS. 3B and 3F illustrate the flow of the signal I through the metal line 140.

FIG. 2B illustrates a top view layout pattern of the I/O circuit 101c including a buffer circuit 103c with an ESD protection circuit 104c in accordance with some embodiments of the present disclosure. The buffer circuit 103c and the ESD protection circuit 104c can correspond to the buffer circuits 103a and the ESD protection circuit 104a of the I/O circuit 101c as shown in FIGS. 2A and 3A-3K. The difference between the I/O circuit 101a shown in FIGS. 2A and 3A-3K and this embodiment is that, the first and second buffer circuit regions 10B and 10C in the I/O circuit 101c have an increased number of transistors 110 arranged along the opposite boundaries of the ESD protection region 10A (e.g., along the Y-direction), such that the overall driving strength of the buffer circuits 103c can be boosted. The additional transistors in regions 10B and 10C enhance the ability of the buffer circuit to drive signals with higher power and efficiency, making the circuit more robust in handling larger loads or faster signal transmission. Furthermore, the placement of additional transistors 110 in the buffer regions 10B and 10C can allow for a more direct and shorter horizontal current path between the buffer circuit 103c and the ESD protection circuit 104c, which in turn minimizes the distance the signal needs to travel and reduces risk of electromigration. The configuration of I/O circuit 101c remains similar to that of I/O circuit 101a. It maintains the same fundamental structure with ESD protection region 10A localized between the first and second buffer circuit regions 10B and 10C.

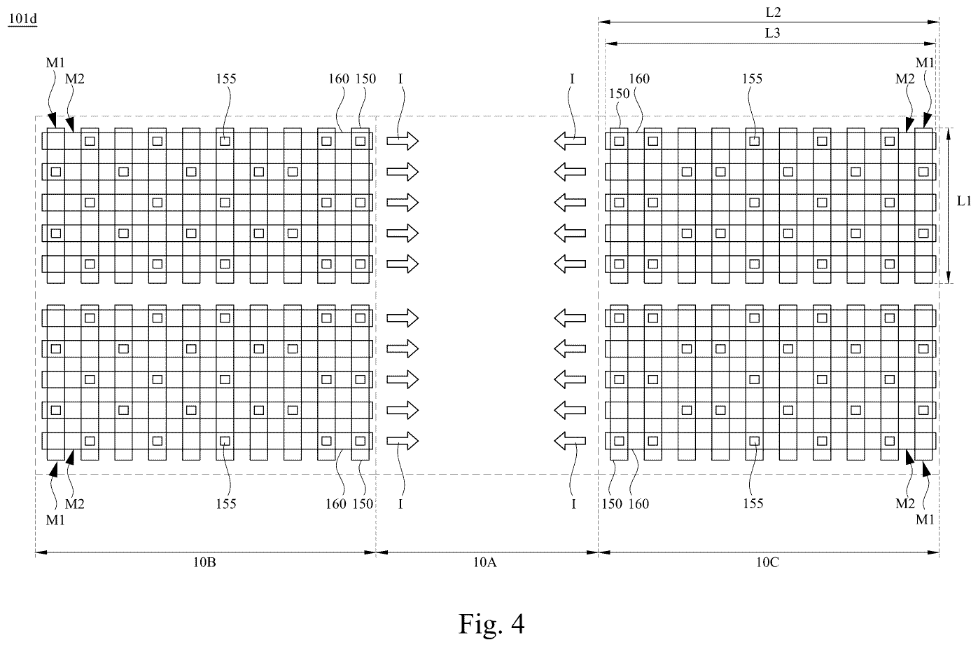

Reference is made to FIG. 4. FIG. 4 illustrates a top view layout pattern of the I/O circuit 101d including a buffer circuit and an ESD protection circuit (not shown) with the metal lines 150 and 160 at the MI level and M2 level and via 155 sandwiched between the metal lines 150 and 160 in accordance with some embodiments of the present disclosure. The buffer circuit and the ESD protection circuit can correspond to the buffer circuits 103c and the ESD protection circuit 104c of the I/O circuit 101c as shown in FIG. 2B. As shown in FIG. 4, the metal line 150 at the M1 level can be split (or cut) to create a forced split in the current path, which in turn distributes the current flow more evenly across the circuit, thereby lowering the risk of electromigration. In some embodiment, the metal line 150 at the M1 level may have a length L1 less than a dimension L2 of the buffer region 10B/10C in a lengthwise direction (or Y-direction) of the metal line 160. In some embodiment, the length L1 of the metal line 150 may be less than a length L3 of the metal line 160.

Additionally, the layout can ensure a balanced or uniform configuration of the underlying vias 155 for each metal line 160 at the M2 level. This means that the number of vias 155 connecting to each metal line 160 is kept consistent across the circuit. In some embodiment, to maintain uniformity, the difference in the number of vias 155 below two adjacent metal lines 160 can be controlled to not exceed a certain threshold, for example, not greater than 5, such as 4, 3, 2, 1, ensuring that no single metal line 160 is disproportionately burdened with current, which could lead to increased EM stress. In some embodiments, the difference in the number of vias 155 below two adjacent metal lines 160 can be controlled to be not greater than 3. The combination of splitting the metal line 150 at the M1 level and balancing the via number at the M2 level can lead to a more evenly distributed current flow. This distribution can reduce localized points of high current density, resulting in greater than about 15% reduction in electromigration stress. In some embodiment, the number of vias 155 of a first group on a first one of the metal lines 160 can be substantially the same as the number of vias 155 of a first group on a second one of the metal lines 160.

Reference is made to FIGS. 5A-5F. FIGS. 5A-5F illustrate schematic cross-sectional views of the I/O circuit 101a corresponding to FIG. 3B at intermediate stages of fabrication process in accordance with some embodiments of the present disclosure. It is understood that additional operations can be provided before, during, and after the processes shown by FIGS. 5A-5F, and some of the operations described below can be replaced or eliminated, for additional embodiments of the method. The order of the operations/processes may be interchangeable.

Reference is made to FIG. 5A. One or more shallow trench isolation (STI) regions 113 are formed in the substrate 50 having the ESD protection circuit region 10A and the buffer circuit region 10B/10C to define the channel regions 111 (see FIGS. 5E and 5F). Formation of the STI regions 113 includes, by way of example and not limitation, etching the substrate 50 to form one or more trenches that define the channel regions 111, depositing one or more dielectric materials (e.g., silicon oxide) to overfill the trenches in the substrate 50, followed by a CMP process to planarize the one or more STI regions 113 with the substrate 50.

In some embodiments, the substrate 50 may include silicon (Si). Alternatively, the substrate 50 may include germanium (Ge), silicon germanium (SiGe), a III-V material (e.g., GaAs, GaP, GaAsP, AlInAs, AlGaAs, GaInAs, InAs, GaInP, InP, InSb, and/or GaInAsP; or a combination thereof) or other appropriate semiconductor materials. In some embodiments, the substrate 50 may include a semiconductor-on-insulator (SOI) structure. For example, the substrate 50 may include a bulk semiconductor substrate, a buried dielectric layer over the bulk substrate, and a semiconductor layer over the buried dielectric layer.

In some embodiments, the depositing one or more dielectric materials of the STI region 113 may be deposited by a CVD process, a sub-atmospheric CVD (SACVD) process, a flowable CVD process, an ALD process, a physical vapor deposition (PVD) process, and/or other suitable processes. In some embodiments, the dielectric layer may include a multi-layer structure, for example, having one or more liner layers. In some embodiments, the STI region 113 may include silicon oxide, silicon nitride, silicon oxynitride, fluorine-doped silicate glass (FSG), a low-k dielectric, combinations thereof, and/or other suitable materials.

Reference is made to FIG. 5B. Once formation of the one or more STI regions 113 is complete, sacrificial gate structures 122 are formed over the channel regions 111 within the ESD protection circuit region 10A and the buffer circuit region 10B/10C. The sacrificial gate structures 122 may include a sacrificial gate dielectric layer 122a and a sacrificial gate 122b over the sacrificial gate dielectric layer 122a. By way of example and not limitation, first a sacrificial gate dielectric material (e.g., silicon oxide, silicon nitride, or the like) may be deposited over the substrate 50, next a sacrificial gate material (e.g., doped or un-doped polysilicon) may be deposited over the dummy gate dielectric material and then planarized (e.g., by CMP), and the sacrificial gate material and sacrificial gate dielectric material are then patterned by using suitable photolithography and etching techniques, resulting in sacrificial gate structures 122 each including sacrificial gate dielectric material and sacrificial gate material to serve as its sacrificial gate dielectric layer 122a and sacrificial gate 122b.

Reference is made to FIG. 5C. Gate spacers 115 are then formed on opposite sidewalls of each sacrificial gate structure 122. Gate spacers 115 may be formed by, for example, deposition and anisotropic etch of a spacer dielectric layer performed after the sacrificial gate patterning is complete. In some embodiments, the spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the sacrificial gate structures 122 while leaving the gate spacers 115 along the sidewalls of the sacrificial gate structures 122.

Reference is made to FIG. 5D. The active regions of substrate 50 exposed by the sacrificial gate structures 122 and the gate spacers 115 can be recessed by suitable process, such as etching. Afterwards, the source/drain regions S/D can be formed over the exposed surfaces of the remaining active regions, and the source/drain. In other words, the source/drain regions S/D can be formed in the active regions and self-aligned to the gate spacers 115. Portions of the active regions (e.g., fin-like structures) between the corresponding source/drain regions S/D can serve as channel regions 111. The source/drain regions S/D may be formed by performing an epitaxial growth process that grows an epitaxy semiconductor material from the active regions. The source/drain regions S/D can be doped with an n-type impurity (e.g., phosphorous) or a p-type impurity (e.g., boron), depending on the conductivity-type of the respective resulting transistors.

Reference is made to FIG. 5E. An ILD layer 116 is then formed over the source/drain regions S/D by first depositing a dielectric material over the substrate 50 and then planarizing the dielectric material (e.g., by using CMP) until the sacrificial gate structures 122 are exposed. Thereafter, the sacrificial gate structures 122 are replaced with the metal gate structures 112. Fabrication of source/drain regions and gate structures of transistors can be referred to as a front-end-of-line (FEOL) processing.

In some embodiments, the ILD layer 116 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the ILD layer 116 may be deposited using any suitable method, such as CVD, physical vapor deposition (PVD), ALD, PEALD, PECVD, SACVD, FCVD, spin-on, and/or the like, or a combination thereof, followed by a CMP process to level the ILD layer 116 with sacrificial gate structures.

After the CMP process is complete, a gate replacement process is carried out to replace the sacrificial gate structures 122 with the metal gate structures 112. The gate replacement process includes, by way of example and not limitation, removing the sacrificial gate structures 122 using one or more etching techniques (e.g., dry etching, wet etching or combinations thereof), thereby creating gate trenches between respective gate spacers 115. Next, a gate dielectric layer 112a comprising one or more dielectrics, followed by a gate electrode layer 112b comprising one or more metals, are deposited to completely fill the gate trenches. Excess portions of the gate dielectric layer 112a and the gate electrode layer 112b are then removed from over the top surface of the ILD layer 116 using, for example, a CMP process. The resulting structure, as illustrated in FIG. 5E, may include remaining portions of the gate dielectric layer 112a and the gate electrode layer 112b inlaid between respective gate spacers 115 to serve as the metal gate structures 112. The materials used in forming the metal gate structures 112 may be deposited by any suitable method, e.g., CVD, PECVD, PVD, ALD, PEALD, electrochemical plating (ECP), electroless plating and/or the like.

In some embodiments, the gate dielectric layer 112a may include dielectric materials such as hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), lanthanum oxide (LaO), zirconium oxide (ZrO), titanium oxide (TiO), tantalum oxide (Ta₂O₅), yttrium oxide (Y₂O₃), strontium titanium oxide (SrTiO₃, STO), barium titanium oxide (BaTiO₃, BTO), barium zirconium oxide (BaZrO), hafnium lanthanum oxide (HfLaO), lanthanum silicon oxide (LaSiO), aluminum silicon oxide (AlSiO), aluminum oxide (Al₂O₃), the like, or combinations thereof. In some embodiments, the gate electrode layer 112b may include TiN, TaN, TiAl, TiAlN, TaAl, TaAlN, TaAlC, TaCN, WNC, Cu, Al, Co, Ni, Pt, W, or combinations thereof.

Reference is made to FIG. 5F. Source/drain contacts 120 can be formed in the ILD layer 116 and on the source/drain regions S/D. In some embodiments, a source/drain silicide region (not shown) can be formed between the source/drain contact 120 and the source/drain regions S/D. Subsequently, source/drain vias 130 can be formed in an ILD layer 117 over the ILD layer 116 and land on the source/drain contacts 120. Gate vias 132 can be formed in the ILD layer 117 and land on the gate structures 112. In some embodiments, the source/drain contacts 120, the source/drain vias 130, and the gate vias 132 may include a metal-containing material such as titanium nitride, titanium oxide, tungsten, cobalt, ruthenium, aluminum, copper, combinations thereof, multi-layers thereof, or the like. The ILD layer 117 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof.

Specifically, once deposition of the ILD layer 116 is complete, the gate vias 132 and the source/drain vias 130 are formed by using photolithography, etching and deposition techniques. For example, a patterned mask may be formed over the ILD layer 116 and used to etch trenches that extend in the ILD layer 116 to expose the source/drain contacts 120 or the gate structures 112. Thereafter, one or more metals are deposited to fill the trenches in the ILD layer 116 by using any acceptable deposition technique (e.g., CVD, ALD, PEALD, PECVD, PVD, ECP, electroless plating, or the like, or any combination thereof). Next, a planarization process (e.g., CMP) may be used to remove excess metals from above the top surface of the ILD layer 116. The remaining metals extend in the ILD layer 116 and constitute the source/drain vias 130 or the gate vias 132 making physical and electrical connections to the source/drain contacts 120 or the gate structures 112.

Subsequently, an interconnect structure 118 can be formed over the gate vias 132 and the source/drain vias 130. The interconnect structure 118 may include, for example, seven metallization layers formed in an IMD (inter-metal dielectric) layer 119, labeled as M0, M1, M2, M3, M4, M5, and M6, with a plurality of layers of metallization via connected therebetween. Other embodiments may contain more or fewer metallization layers and corresponding more or fewer number of vias. The metal line illustrated here just for an example, and the metal line may be otherwise oriented (rotated 90 degrees or at other orientations). In some embodiments, metal lines disposed at the M0 level over the substrate 50 may include a power supply voltage line Vss (see FIGS. 2A, 3J, and 3K), a power supply voltage line Vdd (see FIGS. 2A, 3J, and 3K), a metal line 140, and a metal line 142 (see FIGS. 3E and 3I). The metal lines disposed at the M1 level over the M0 level may include metal lines 150 (see FIGS. 3A, 3B, and 3F). The metal lines disposed at the M2 level over the M1 level may include metal lines 160. Although not shown (for the sake of simplicity and clarity), additional metal lines are also formed over the interconnect structure 118. In some embodiments, the metallization layers may include a metal-containing material such as titanium nitride, titanium oxide, tungsten, cobalt, ruthenium, aluminum, copper, combinations thereof, multi-layers thereof, or the like. The IMD layer 119 may be made of an oxide, such as silicon oxide, a nitride, such as silicon nitride, the like, or a combination thereof, which may be formed by a chemical vapor deposition (CVD) process, such as high density plasma CVD (HDP-CVD), flowable chemical vapor deposition (FCVD), the like, or a combination thereof. In some embodiments, the metal lines and/or the metal vias in each of the metallization layers may include a metal-containing material such as titanium nitride, titanium oxide, tungsten, cobalt, ruthenium, aluminum, copper, combinations thereof, multi-layers thereof, or the like.

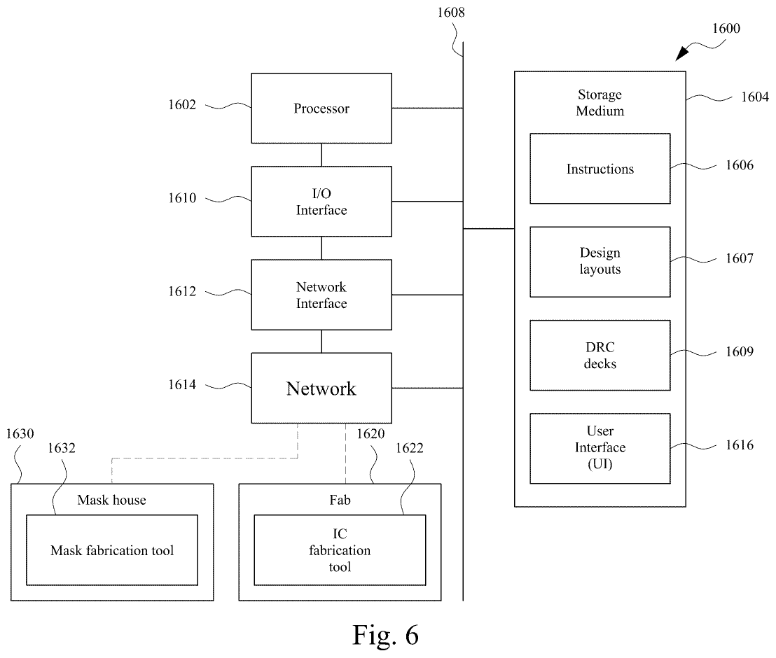

Reference is made to FIG. 6. FIG. 6 is a schematic diagram of an electronic design automation (EDA) system in accordance with some embodiments of the present disclosure. Methods described herein of generating design layouts, e.g., layouts of the I/O circuit 101a, 101b, 101c, and/or 101d as discussed above, in accordance with one or more embodiments, are implementable, for example, using EDA system 1600, in accordance with some embodiments. At least I/O circuit 101a, 101b, 101c, and/or 101d is manufactured by a corresponding layout design similar to the corresponding integrated circuit. For brevity FIGS. 1A-5F are described as corresponding integrated circuits, but in some embodiments, FIGS. 1A-5F also correspond to layout designs with corresponding patterns similar to I/O circuit 101a, 101b, 101c, and/or 101d with corresponding structures, and pattern relationships including alignment, lengths and widths, as well as configurations and layers of a corresponding layout design are similar to the structural relationships and configurations and layers of the corresponding integrated circuit, and similar detailed description will not be described for brevity. In some embodiments, EDA system 1600 is a computing device that is capable of executing one or more automatic placement & routing (APR) operations. The EDA system 1600 including a hardware processor 1602 and a non-transitory, computer-readable storage medium 1604. Computer-readable storage medium 1604, amongst other things, is encoded with, i.e., stores, a set of executable instructions 1606, design layouts 1607, design rule check (DRC) decks 1609 or any intermediate data for executing the set of instructions. Each design layout 1607 may include a graphical representation of an integrated chip, such as for example, a GSII file. Each DRC deck 1609 may include a list of design rules specific to a semiconductor process chosen for fabrication of a design layout 1607. Execution of instructions 1606, design layouts 1607 and DRC decks 1609 by hardware processor 1602 represents (at least in part) an EDA tool which implements a portion or all of, e.g., the methods described herein in accordance with one or more (hereinafter, the noted processes and/or methods).

Processor 1602 is electrically coupled to computer-readable storage medium 1604 via a bus 1608. Processor 1602 is also electrically coupled to an I/O interface 1610 by bus 1608. A network interface 1612 is also electrically connected to processor 1602 via bus 1608. Network interface 1612 is connected to a network 1614, so that processor 1602 and computer-readable storage medium 1604 are capable of connecting to external elements via network 1614. Processor 1602 is configured to execute instructions 1606 encoded in computer-readable storage medium 1604 in order to cause EDA system 1600 to be usable for performing a portion or all of the noted processes and/or methods. In one or more embodiments, processor 1602 is a central processing unit (CPU), a multi-processor, a distributed processing system, an application specific integrated circuit (ASIC), and/or a suitable processing unit.

In one or more embodiments, computer-readable storage medium 1604 is an electronic, magnetic, optical, electromagnetic, infrared, and/or a semiconductor system (or apparatus or device). For example, computer-readable storage medium 1604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 1604 includes a compact disk-read only memory (CD-ROM), a compact disk-read/write (CD-R/W), and/or a digital video disc (DVD).

In one or more embodiments, computer-readable storage medium 1604 stores instructions 1606, design layouts 1607 (e.g., layouts of the I/O circuit 101a, 101b, 101c, and/or 101d as discussed previously) and DRC decks 1609 configured to cause EDA system 1600 (where such execution represents (at least in part) the EDA tool) to be usable for performing a portion or all of the noted processes and/or methods. In one or more embodiments, storage medium 1604 also stores information which facilitates performing a portion or all of the noted processes and/or methods.

EDA system 1600 includes I/O interface 1610. I/O interface 1610 is coupled to external circuitry. In one or more embodiments, I/O interface 1610 includes a keyboard, keypad, mouse, trackball, trackpad, touchscreen, and/or cursor direction keys for communicating information and commands to processor 1602.

EDA system 1600 also includes network interface 1612 coupled to processor 1602. Network interface 1612 allows EDA system 1600 to communicate with network 1614, to which one or more other computer systems are connected. Network interface 1612 includes wireless network interfaces such as BLUETOOTH, WIFI, WIMAX, GPRS, or WCDMA; or wired network interfaces such as ETHERNET, USB, or IEEE-1388. In one or more embodiments, a portion or all of noted processes and/or methods, is implemented in two or more EDA systems 1600.

EDA system 1600 is configured to receive information through I/O interface 1610. The information received through I/O interface 1610 includes one or more of instructions, data, design rules, libraries of standard cells, and/or other parameters for processing by processor 1602. The information is transferred to processor 1602 via bus 1608. EDA system 1600 is configured to receive information related to a user interface (UI) 1616 through I/O interface 1610. The information is stored in computer-readable medium 1604 as UI 1616.

Also illustrated in FIG. 6 are fabrication tools associated with the EDA system 1600. For example, a mask house 1630 receives a design layout from the EDA system 1600 by, for example, the network 1614, and the mask house 1630 has a mask fabrication tool 1632 (e.g., a mask writer) for fabricating one or more photomasks (e.g., photomasks used for fabricating I/O circuit 101a, 101b, 101c, and/or 101d as discussed above) based on the design layout generated from the EDA system 1600. An IC fabricator (“Fab”) 1620 may be connected to the mask house 1630 and the EDA system 1600 by, for example, the network 1614. Fab 1620 includes an IC fabrication tool 1622 for fabricating IC chips (e.g., layouts of the I/O circuit 101a, 101b, 101c, and/or 101d as discussed above) using the photomasks fabricated by the mask house 1630. By way of example and not limitation, the IC fabrication tool 1622 includes one or more cluster tools for fabricating IC chips. The cluster tool may be a multiple reaction chamber type composite equipment which includes a polyhedral transfer chamber with a wafer handling robot inserted at the center thereof, a plurality of process chambers (e.g., CVD chamber, PVD chamber, etching chamber, annealing chamber or the like) positioned at each wall face of the polyhedral transfer chamber; and a loadlock chamber installed at a different wall face of the transfer chamber.

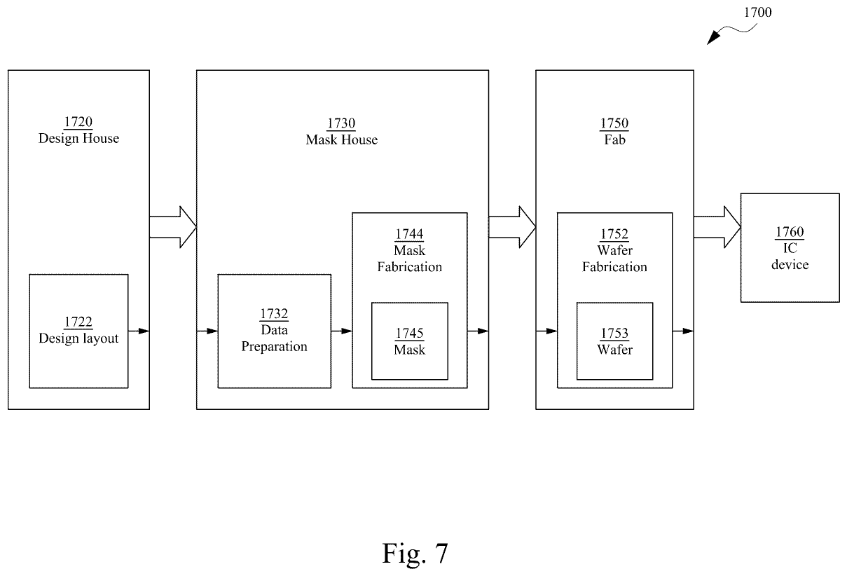

Reference is made to FIG. 7. FIG. 7 is a block diagram of an IC manufacturing system and an IC manufacturing flow associated therewith, in accordance with some embodiments of the present disclosure. In some embodiments, based on one or more design layouts, e.g., layouts of the I/O circuit 101a, 101b, 101c, and/or 101d as discussed above, one or more photomasks and one or more integrated circuits are fabricated using manufacturing system 1700.

In FIG. 7, an IC manufacturing system 1700 includes entities, such as a design house 1720, a mask house 1730, and a Fab 1750, that interact with one another in the design, development, and manufacturing cycles and/or services related to manufacturing ICs 1760. The entities in IC manufacturing system 1700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1720, mask house 1730, and Fab 1750 is owned by a single larger company. In some embodiments, two or more of design house 1720, mask house 1730, and Fab 1750 coexist in a common facility and use common resources.

Design house (or design team) 1720 generates design layouts 1722 (e.g., layouts of the I/O circuit 101a, 101b, 101c, and/or 101d as discussed above). Design layouts 1722 include various geometrical patterns designed for ICs 1760 (e.g., I/O circuit 101a, 101b, 101c, and/or 101d with resistor circuits as discussed above). The geometrical patterns correspond to patterns of metal, oxide, or semiconductor layers that make up the various components of ICs 1760 to be fabricated. The various layers combine to form various device features. For example, a portion of design layout 1722 includes various circuit features, such as active regions, passive regions, functional gate structures, resistor structures, gate contacts, resistor contacts, source/drain contacts, and/or metal lines, to be formed on a semiconductor wafer. Design house 1720 implements a proper design procedure to form design layout 1722. The design procedure includes one or more of logic design, physical design or place and route. Design layout 1722 is presented in one or more data files having information of the geometrical patterns and a netlist of various nets. For example, design layout 1722 can be expressed in a GDSII file format or DFII file format.

Mask house 1730 includes data preparation 1732 and mask fabrication 1744. Mask house 1730 uses design layout 1722 (e.g., layout of the I/O circuit 101a, 101b, 101c, and/or 101d as discussed above) to manufacture one or more photomasks 1745 to be used for fabricating the various layers of IC 1760 according to design layout 1722. Mask house 1730 performs mask data preparation 1732, where design layout 1722 is translated into a representative data file (“RDF”). Mask data preparation 1732 provides the RDF to mask fabrication 1744. Mask fabrication 1744 includes a mask writer. A mask writer converts the RDF to an image on a substrate, such as a photomask (reticle) 1745. Design layout 1722 is manipulated by mask data preparation 1732 to comply with particular characteristics of the mask writer and/or rules of fab 1750. In FIG. 7, mask data preparation 1732 and mask fabrication 1744 are illustrated as separate elements. In some embodiments, mask data preparation 1732 and mask fabrication 1744 can be collectively referred to as mask data preparation.

In some embodiments, mask data preparation 1732 includes optical proximity correction (OPC) which uses lithography enhancement techniques to compensate for image errors, such as those that can arise from diffraction, interference, other process effects and the like. OPC adjusts design layout 1722. In some embodiments, mask data preparation 1732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1732 includes a mask rule checker (MRC) that checks design layout 1722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies design layout 1722 diagram to compensate for limitations during mask fabrication 1744, which may undo part of the modifications performed by OPC in order to meet mask creation rules.

In some embodiments, mask data preparation 1732 includes lithography process checking (LPC) that simulates processing that will be implemented by Fab 1750 to fabricate ICs 1760. LPC simulates this processing based on design layout 1722 to create a simulated manufactured integrated circuit, such as IC 1760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine design layout 1722.

After mask data preparation 1732 and during mask fabrication 1744, a photomask 1745 or a group of photomasks 1745 are fabricated based on the design layout 1722. In some embodiments, mask fabrication 1744 includes performing one or more lithographic exposures based on the design layout 1722. In some embodiments, an electron-beam (e-beam) or a mechanism of multiple e-beams is used to form a pattern on a photomask 1745 based on design layout 1722. Photomask 1745 can be formed in various technologies. In some embodiments, photomask 1745 is formed using binary technology. In some embodiments, a mask pattern includes opaque regions and transparent regions. A radiation beam, such as an ultraviolet (UV) beam, used to expose the radiation sensitive material layer (e.g., photoresist) which has been coated on a wafer, is blocked by the opaque regions and transmits through the transparent regions. In one example, a binary mask version of photomask 1745 includes a transparent substrate (e.g., fused quartz) and an opaque material (e.g., chromium) coated in the opaque regions of the binary mask. In another example, photomask 1745 is formed using a phase shift technology. In a phase shift mask (PSM) version of photomask 1745, various features in the pattern formed on the phase shift photomask are configured to have proper phase difference to enhance the resolution and imaging quality. In various examples, the phase shift photomask can be attenuated PSM or alternating PSM. The photomask(s) generated by mask fabrication 1744 is used in a variety of processes. For example, such a mask(s) is used in an ion implantation process to form various doped regions in semiconductor wafer 1753, in an etching process to form various etching regions in semiconductor wafer 1753, and/or in other suitable processes.

Fab 1750 may include wafer fabrication 1752. Fab 1750 is an IC fabrication business that includes one or more manufacturing facilities for the fabrication of a variety of different IC products. In some embodiments, Fab 1750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (BEOL fabrication), and a third manufacturing facility may provide other services for the foundry business.

Fab 1750 uses photomask(s) 1745 fabricated by mask house 1730 to fabricate ICs 1760. Thus, fab 1750 at least indirectly uses design layout(s) 1722 (e.g., layouts of the I/O circuit 101a, 101b, 101c, and/or 101d as discussed above) to fabricate ICs 1760. In some embodiments, wafer 1753 is processed by fab 1750 using photomask(s) 1745 to form ICs 1760. In some embodiments, the device fabrication includes performing one or more photolithographic exposures based at least indirectly on design layout 1722.

Therefore, based on the above discussions, it can be seen that the present disclosure offers advantages. It is understood, however, that other embodiments may offer additional advantages, and not all advantages are necessarily disclosed herein, and that no particular advantage is required for all embodiments. The present disclosure in various embodiments provides a method to enhance the performance of die-to-die I/O circuits in 3DIC. The I/O circuit can integrate a buffer circuit with an ESD protection structure. A driving strength of the buffer circuit (e.g., 16 PMOS and 16 NMOS transistors) can be divided into two sub-buffer regions (e.g., buffer circuit regions 10B and 10C shown in FIG. 2A), each wielding half of the total driving strength (e.g., 8 PMOS and 8 NMOS). Specifically, for output stage, the transistors in the sub-buffer regions connect their source/drain regions to those in the ESD protection region via a horizontal metal line. The two sub-buffer regions can be positioned on opposite sides of the ESD protection region (e.g., ESD protection circuit region 10A shown in FIG. 2A). This arrangement can split and shorten the horizontal current path, reducing the length of the current path to between 50% and 75% of its original length, leading to a decrease in output capacitance loading and boosts electromigration resilience.

In some embodiments, a method includes forming first and second transistors over a substrate, the first and second transistors being parts of a buffer circuit in an input/output (I/O) circuit; forming a third transistor over the substrate and interposing between the first and second transistors from a cross-sectional view, the third transistor being a part of an electrostatic discharge (ESD) circuit in the I/O circuit; forming a first metal line horizontally extending from above the first transistor across the third transistor to above the second transistor, wherein the first metal line is electrically coupled to the first, second, and third transistors. In some embodiments, the buffer circuit is a tri-state buffer circuit. In some embodiments, the buffer circuit is an transmitter. In some embodiments, the first metal line is electrically connected from a source/drain region of the first transistor of the buffer circuit to a source/drain region of the third transistor of the ESD circuit. In some embodiments, the method further includes before forming the first metal line, forming a second metal line over the source/drain region of the first transistor, wherein the second metal line is electrically connected to the source/drain region of the first transistor, and after forming the first and second metal lines, the second metal line extends in a direction perpendicular to a lengthwise direction of the first metal line from a top view. In some embodiments, from the top view, a length of the second metal line is less than a length of the first metal line. In some embodiments, the method further includes before forming the first metal line, forming a plurality of metal vias over the substrate, wherein after forming the first metal line, a first group of the metal vias is direct below and in contact with the first metal line; forming a second metal line at a same elevation as the first metal line, wherein the second metal line is electrically connected to the buffer circuit and the ESD circuit, a second group of the metal vias is direct below and in contact with the second metal line, and a difference in a number of the first and second groups of the metal vias is not greater than 3. In some embodiments, the method further includes forming a third metal line at a same elevation as the first and second metal lines, wherein the third metal line is electrically connect to the buffer circuit and the ESD circuit, a third group of the metal vias is direct below and in contact with the third metal line, and a difference in a number of the first and third groups of the metal vias is not greater than 3. In some embodiments, a difference in a number of the second and third groups of the metal vias is not greater than 3. In some embodiments, the method further includes before forming the first metal line, forming a metal contact over a source/drain region of the first transistor; forming a metal via over the metal contact, wherein after forming the first metal line, the first metal line lands on the metal via.

In some embodiments, a method includes forming a plurality of first source/drain regions over a first buffer circuit region of a substrate, a plurality of second source/drain regions over a second buffer circuit region of the substrate, and a plurality of third source/drain regions over an electrostatic discharge (ESD) circuit region of the substrate, wherein the first, second, and third source/drain regions are parts of an input/output (I/O) circuit of a first die, and the ESD circuit region is localized between the first and second buffer circuit regions from a top view; forming a plurality of first gate strips over the first buffer circuit region and interleaving with the first source/drain regions from the top view, a plurality of second gate strips over the second buffer circuit region and interleaving with the second source/drain regions from the top view, and a plurality of third gate strips over the ESD circuit region and interleaving with the third source/drain regions from the top view; forming a metal line over the first and second buffer circuit regions and the ESD circuit region, the metal line electrically coupling one of the first source/drain regions, one of the second source/drain regions, and one of the third source/drain regions. In some embodiments, the method further includes forming a first metal pad over the metal line, wherein the first metal pad is electrically coupled to the metal line. In some embodiments, the method further includes bonding the first metal pad of the first die to a second metal pad of a second die. In some embodiments, the metal line extends across the first, second, and third gate strips. In some embodiments, the method further includes forming a plurality of fourth gate strips over the first buffer circuit region, and a plurality of fifth gate strips over the second buffer circuit region, wherein the first and fourth gate strips are arranged along a lengthwise direction of one of the first gate, the second and fifth gate strips are arranged along a lengthwise direction of one of the second gate strip, the fourth and fifth gate strips are parts of the I/O circuit of the first die.

In some embodiments, a semiconductor structure includes a first transistor, a second transistor, and a a third transistor. The first transistor is over an electrostatic discharge (ESD) circuit region of a substrate. The second transistor is over a first buffer circuit region of the substrate. The first buffer circuit region is at a first side of the ESD circuit region from a top view. The third transistor is over a second buffer circuit region of the substrate. The first, second, and third transistors are parts of an input/output circuit of a first die, and the second buffer circuit region is at a second side of the ESD circuit region opposite to the first side of the ESD circuit region from the top view. In some embodiments, the semiconductor structure further includes a first metal line horizontal extending above the first and second buffer circuit regions and the ESD circuit region, wherein the first metal line is electrically coupled to a source/drain region of the first transistor, a source/drain region of the second transistor, and a source/drain region of the third transistor. In some embodiments, the semiconductor structure further includes a second metal line, a plurality of first vias, and a plurality of second vias. The second metal line extends above the first and second buffer circuit regions and the ESD circuit region and at a same elevation as the first metal line. The first vias are in contact with a bottom surface of the first metal line. The second vias are in contact with a bottom surface of the second metal line. A difference in a number of the first vias and the second vias is not greater than 3. In some embodiments, the semiconductor structure further includes a pad over the first metal line, wherein the pad is electrically coupled to the first metal line. In some embodiments, the second and third transistors are parts of a tri-state buffer circuit, an inverter circuit, or a combination thereof.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming first and second transistors over a substrate, the first and second transistors being parts of a buffer circuit in an input/output (I/O) circuit;
forming a third transistor over the substrate and interposing between the first and second transistors from a cross-sectional view, the third transistor being a part of an electrostatic discharge (ESD) circuit in the I/O circuit; and
forming a first metal line horizontally extending from above the first transistor across the third transistor to above the second transistor, wherein the first metal line is electrically coupled to the first, second, and third transistors.

2. The method of claim 1, wherein the buffer circuit is a tri-state buffer circuit.

3. The method of claim 1, wherein the buffer circuit is a transmitter.

4. The method of claim 1, wherein the first metal line is electrically connected from a source/drain region of the first transistor of the buffer circuit to a source/drain region of the third transistor of the ESD circuit.

5. The method of claim 4, further comprising:
before forming the first metal line, forming a second metal line over the source/drain region of the first transistor, wherein the second metal line is electrically connected to the source/drain region of the first transistor, and after forming the first and second metal lines, the second metal line extends in a direction perpendicular to a lengthwise direction of the first metal line from a top view.

6. The method of claim 5, wherein from the top view, a length of the second metal line is less than a length of the first metal line.

7. The method of claim 1, further comprising:
before forming the first metal line, forming a plurality of metal vias over the substrate, wherein after forming the first metal line, a first group of the metal vias is direct below and in contact with the first metal line; and
forming a second metal line at a same elevation as the first metal line, wherein the second metal line is electrically connected to the buffer circuit and the ESD circuit, a second group of the metal vias is direct below and in contact with the second metal line, and a difference in a number of the first and second groups of the metal vias is not greater than 3.

8. The method of claim 7, further comprising:
forming a third metal line at a same elevation as the first and second metal lines, wherein the third metal line is electrically connected to the buffer circuit and the ESD circuit, a third group of the metal vias is direct below and in contact with the third metal line, and a difference in a number of the first and third groups of the metal vias is not greater than 3.

9. The method of claim 8, wherein a difference in a number of the second and third groups of the metal vias is not greater than 3.

10. The method of claim 1, further comprising:
before forming the first metal line, forming a metal contact over a source/drain region of the first transistor; and
forming a metal via over the metal contact, wherein after forming the first metal line, the first metal line lands on the metal via.

11. A method, comprising:
forming a plurality of first source/drain regions over a first buffer circuit region of a substrate, a plurality of second source/drain regions over a second buffer circuit region of the substrate, and a plurality of third source/drain regions over an electrostatic discharge (ESD) circuit region of the substrate, wherein the first, second, and third source/drain regions are parts of an input/output (I/O) circuit of a first die, and the ESD circuit region is localized between the first and second buffer circuit regions from a top view;
forming a plurality of first gate strips over the first buffer circuit region and interleaving with the first source/drain regions from the top view, a plurality of second gate strips over the second buffer circuit region and interleaving with the second source/drain regions from the top view, and a plurality of third gate strips over the ESD circuit region and interleaving with the third source/drain regions from the top view; and
forming a metal line over the first and second buffer circuit regions and the ESD circuit region, the metal line electrically coupling one of the first source/drain regions, one of the second source/drain regions, and one of the third source/drain regions.

12. The method of claim 11, further comprising:
forming a first metal pad over the metal line, wherein the first metal pad is electrically coupled to the metal line.

13. The method of claim 12, further comprising:
bonding the first metal pad of the first die to a second metal pad of a second die.

14. The method of claim 11, wherein the metal line extends across the first, second, and third gate strips.

15. The method of claim 11, further comprising:
forming a plurality of fourth gate strips over the first buffer circuit region, and a plurality of fifth gate strips over the second buffer circuit region, wherein the first and fourth gate strips are arranged along a lengthwise direction of one of the first gate strips, the second and fifth gate strips are arranged along a lengthwise direction of one of the second gate strip, the fourth and fifth gate strips are parts of the I/O circuit of the first die.

16. A semiconductor structure, comprising:
a first transistor over an electrostatic discharge (ESD) circuit region of a substrate;
a second transistor over a first buffer circuit region of the substrate, wherein the first buffer circuit region is at a first side of the ESD circuit region from a top view; and
a third transistor over a second buffer circuit region of the substrate, wherein the first, second, and third transistors are parts of an input/output circuit of a first die, and the second buffer circuit region is at a second side of the ESD circuit region opposite to the first side of the ESD circuit region from the top view.

17. The semiconductor structure of claim 16, further comprising:
a first metal line horizontal extending above the first and second buffer circuit regions and the ESD circuit region, wherein the first metal line is electrically coupled to a source/drain region of the first transistor, a source/drain region of the second transistor, and a source/drain region of the third transistor.

18. The semiconductor structure of claim 17, further comprising:
a second metal line extending above the first and second buffer circuit regions and the ESD circuit region and at a same elevation as the first metal line;
a plurality of first vias in contact with a bottom surface of the first metal line; and
a plurality of second vias in contact with a bottom surface of the second metal line, wherein a difference in a number of the first vias and the second vias is not greater than 3.

19. The semiconductor structure of claim 17, further comprising:
a pad over the first metal line, wherein the pad is electrically coupled to the first metal line.

20. The semiconductor structure of claim 16, wherein the second and third transistors are parts of a tri-state buffer circuit, an inverter circuit, or a combination thereof.
